(19) United States
(12) Patent Application Publication
(10) Pub. No.: US 2011/0312150 A1
(43) Pub. Date: Dec. 22, 2011

(54) PHASE CHANGE MEMORY DEVICES AND METHODS FOR FABRICATING THE SAME

(75) Inventors: Chien-Min Lee, Kaohsiung City (TW); Ming-Jeng Huang, Taichung City (TW); Jen-Chi Chuang, Hsinchu County (TW); Jia-Yo Lin, Hsinchu City (TW); Min-Chih Wang, Taipei County (TW)

(73) Assignee: POWERCHIP SEMICONDUCTOR CORP., HSIN-CHU (TW)

(21) Appl. No.: 13/219,568

(22) Filed: Aug. 26, 2011

Related U.S. Application Data
(62) Division of application No. 12/552,826, filed on Sep. 2, 2009.

(30) Foreign Application Priority Data
Nov. 28, 2008 (TW) TW097146226

(51) Int. Cl. H01L 47/00

(52) U.S. Cl. 438/382; 257/E47.005

(57) ABSTRACT

A phase change memory device is provided, including a substrate, a first dielectric layer disposed over the substrate, a first electrode disposed in the first dielectric layer, a second dielectric layer formed over the first dielectric layer, covering the first electrode, a heating electrode disposed in the second dielectric layer, contacting the first electrode, a phase change material layer disposed over the second dielectric layer, contacting the heating electrode, and a second electrode disposed over the phase change material layer. In one embodiment, the heating electrode includes a first portion contacting the first electrode and a second portion contacting the phase change material layer, and the second portion of the heating electrode includes metal silicides and the first portion of the heating electrode includes no metal silicides.

### CROSS REFERENCE TO RELATED APPLICATIONS

This application claims priority of Taiwan Patent Application No. 97146226 filed on Nov. 28, 2008, the entirety of which is incorporated by reference herein.

### BACKGROUND OF THE INVENTION

1. Field of the Invention

The invention relates to semiconductor memory devices, and more particularly to a non-volatile phase change memory (PCM) device and a method for fabricating the same.

2. Description of the Related Art

Phase change memory devices are non-volatile, highly programmable, and highly scalable with decreasing trend in driving voltage/current. The trend in phase change memory development nowadays is to increase cell density and thus requires less driving current thereof.

The main functional material, phase change material, in a phase change memory device is operated between two solid phases, one crystalline state and the other amorphous state. Transformation between these two phases can be achieved by heating and then cooling the phase change material in different ways. The phase change material exhibits different electrical characteristics depending on its state. For example, in the amorphous state the material exhibits a higher resistivity than in the crystalline state. Such phase transformation with variable electrical resistivities can be performed within nanoseconds time scale with the input of pico joules of energy. Since phase change material permits reversible phase transformation, the bit status can be distinguished according to the state it is.

FIG. 1 is a schematic diagram showing a cross sectional view of a conventional phase change memory cell structure. As shown in FIG. 1, the phase change memory cell structure includes a silicon substrate 10 with a bottom electrode 12 thereon. A dielectric layer 14 is formed over the bottom electrode 12 and a heating electrode 16 is formed in a portion of the dielectric layer 14. Moreover, a patterned phase change material layer 20 is stacked over the dielectric layer 14. The patterned phase change material layer 20 is formed within a dielectric layer 18 which is formed over the dielectric layer 14 and a bottom surface of the phase change material layer 20 partially contacts the heating electrode 16. A dielectric layer 24 is formed over the dielectric layer 18 and a top electrode 22 is formed over and in the dielectric layer 24. The top electrode 22 partially covers the dielectric layer 24 and portions thereof protrude downward through the dielectric layer 24, thereby contacting the phase change material layer 20 thereunder.

In a write mode, an electrical current is injected to the heating electrode 16 and flows therethrough, thus heating up the interface between the phase change material layer pattern 20 and the heating electrode 16 and thereby transforming a portion (not shown) of the phase change material layer 20 into either the amorphous state or the crystalline state depending on the duration and amplitude of the current that flows through the heating electrode 16.

Nevertheless, the trend for phase change memory development is to increase the memory capacity by scaling down the unit cell size. With the reduction of the phase change memory cell size, the selecting transistor should be scaled down as well thus limiting the scale of providing current. Therefore the programming current (RESET to amorphous state and SET to crystalline state) for phase change memory cell has to be kept under the capability of the corresponding transistor.

The most effective strategy to reduce the programming current is to reduce the contact area between the heating electrode 16 and the phase change material layer 20, such as through reducing the diameter D₀ of the heating electrode 16, thereby reducing the phase change volume and requirement of the programming current. Generally the minimum size of heating electrode 16's diameter D₀ is limited by the photolithography capability. To further reduce the diameter D₀, this invention proposes an alternative approach beyond the photolithography limitation.

### BRIEF SUMMARY OF THE INVENTION

An exemplary embodiment of a phase change memory device comprises a substrate, a first dielectric layer disposed over the substrate, a first electrode disposed in the first dielectric layer, a second dielectric layer formed over the first dielectric layer, covering the first electrode, a heating electrode disposed in the second dielectric layer, contacting the first electrode, a phase change material layer disposed over the second dielectric layer, contacting the heating electrode, and a second electrode disposed over the phase change material layer. In one embodiment, the heating electrode comprises a first portion contacting the first electrode and a second portion contacting the phase change material layer, and the second portion of the heating electrode comprises metal silicides and the first portion of the heating electrode comprises no metal silicides.

An exemplary embodiment of a method for fabricating a phase change memory device comprises providing a substrate with a first electrode formed thereover. A first dielectric layer is formed over the substrate, wherein the first dielectric layer surrounds the first electrode and exposes a top surface of the first electrode. A second dielectric layer is formed over the first dielectric layer, covering the first electrode and the first dielectric layer. A heating electrode is formed in the second dielectric layer. A phase change material layer is formed over the second dielectric layer. A second electrode is formed over the phase change material layer to contact thereof. In one embodiment, the heating electrode comprises a first portion contacting the first electrode and a second portion contacting the phase change material layer, and the second portion of the heating electrode comprises metal silicides and the first portion of the heating electrode comprises doped polysilicon, noble metal materials or refractory metal materials.

A detailed description is given in the following embodiments with reference to the accompanying drawings.

### BRIEF DESCRIPTION OF THE DRAWINGS

The invention can be more fully understood by reading the subsequent detailed description and examples with references made to the accompanying drawings, wherein:

FIG. 1 is cross section of a conventional phase change memory device;

FIGS. 2-7 are cross sections showing a method for fabricating a phase change memory device according to an embodiment of the invention;

FIG. 8 is cross section of a phase change memory device according to another embodiment of the invention; and

FIGS. 9-14 are cross sections showing a method for fabricating a phase change memory device according to yet another embodiment of the invention.

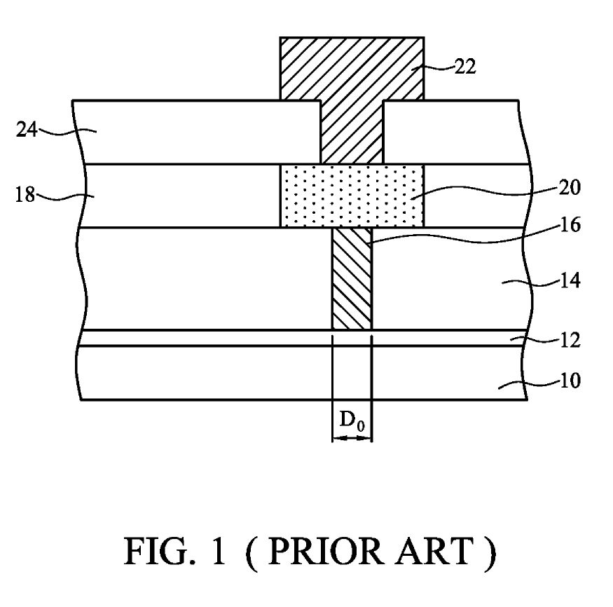

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

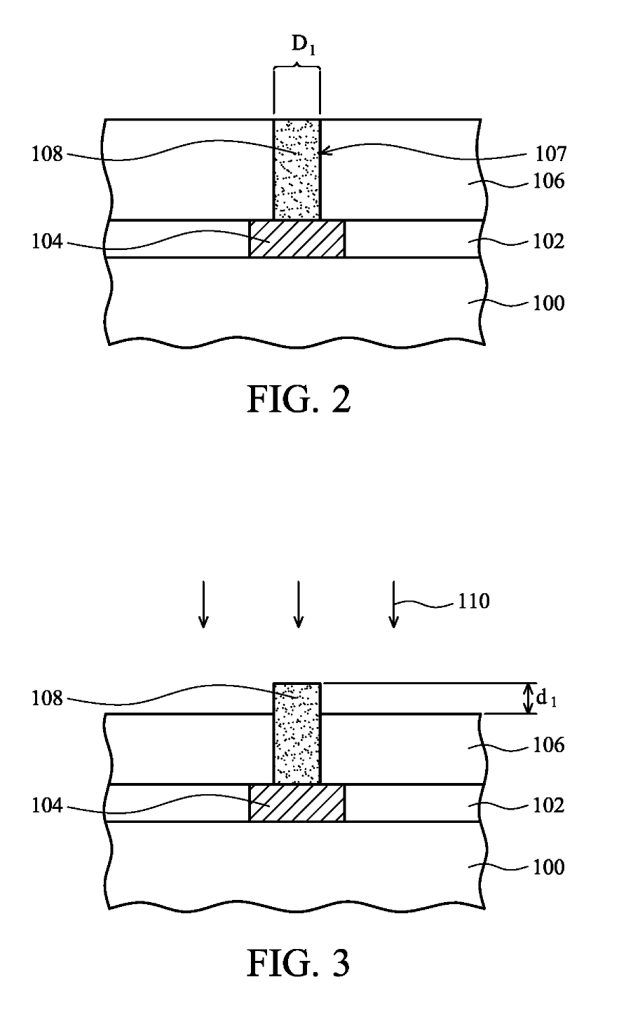

Embodiments of phase change memory devices and methods for fabricating the same are described as below incorporating FIGS. 2-14.

FIGS. 2-7 are schematic diagrams showing fabrication steps of a method for fabricating a phase change memory device according to an exemplary embodiment. In this embodiment, only fabricating of a phase change memory cell in a phase change memory device is illustrated. Note that the phase change memory device in this embodiment can be further formed with a plurality of phase change memory cells and is not limited to the illustrations in FIGS. 2-7.

Referring to FIG. 2, a semiconductor structure such as a silicon substrate is first provided, having semiconductor devices and/or other conductive interconnecting structures covered by a dielectric layer formed thereon. The semiconductor devices (not shown) can be, for example, transistors or diodes. For those skilled in the art, the above active device can be electrically connected with the phase change memory cell by conductive interconnecting structures formed at suitable locations, thereby controlling memory status of the memory cell. The active devices and conductive components, however, are not shown in FIG. 2 for simplicity and only a planar substrate 100 is illustrated in FIG. 2.

Next, an electrode 104 is formed over the substrate 100. As shown in FIG. 2, the electrode 104 can be, for example, a metal line extending along a direction perpendicular to the surface of FIG. 2 or a metal plug. The electrode 104 is disposed over a portion of the substrate 100. Herein, as an example of forming a metal line, a layer of conductive material such as Ti, TiN, TiW, W, WN, WSi, TaN, or doped polysilicon, is first blanketly formed over the substrate 100 by methods such as chemical vapor deposition or sputtering. A photolithography process (not shown) is then performed to remove portions of the layer of conductive material to form the electrode 104.

Next, a layer of dielectric material is blanketly formed over the substrate 100 to cover the electrode 104. Herein, the dielectric material can be, for example, borophosphosilicate glass (BPSG), silicon oxide or silicon nitride. A planarization process (not shown) is then performed to remove the portion of the dielectric material over the electrode 104, thus leaving a dielectric layer 102 over the substrate 100 to surround the electrode 104.

Next, a dielectric layer 106 is blanketly formed over the dielectric layer 102. The dielectric layer may comprise silicon dioxide formed by a high density plasma chemical vapor deposition process. A photolithography and etching process (not shown) are then performed to define the dielectric layer 106, thereby forming an opening 107 therein. As shown in FIG. 2, the opening 107 penetrates the dielectric layer 106 and exposes a portion of the electrode 104. The opening 107 has a diameter D₁ of about 90-110 nm.

Next, a layer of conductive material is deposited over the dielectric layer 106 and fills the opening 107. A planarization process (not shown) is then performed to remove the conductive material over the dielectric layer 106, thereby forming a heating electrode 108 in the opening 107. In this embodiment, the heating electrode 108 may comprise polysilicon doped with n type or p type dopants and is electrically conductive.

Referring to FIG. 3, an etching process 110 is performed to selectively remove portions of the dielectric layer 106 and expose portions of the heating electrode 108. Herein the etching process 110 preferably is a wet etching process and a thickness d1 of about 130-150 nm of the dielectric layer 106 is removed after the etching process 110, thereby partially exposing portions of the heating electrode 108.

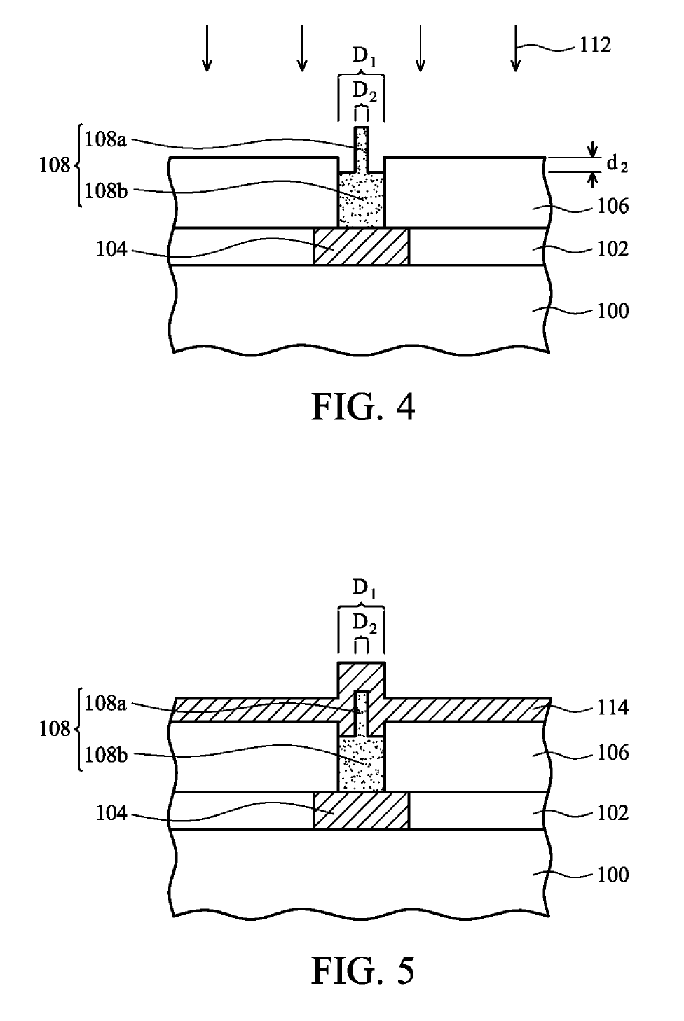

Referring to FIG. 4, an etching process 112 is then performed to selectively remove portions of the heating electrode 108 exposed by the dielectric layer 106. Herein, the etching process 112 preferably is a wet etching process and portions of the heating electrode 108 exposed by the dielectric layer 106 are removed after the etching process 112, thereby forming the heating electrode 108 with a reversed T shaped cross section.

As shown in FIG. 4, after the etching process 112, the heating electrode 108 is substantially divided into two portions: one is a first portion 108b not treated by the etching process 112; and the other is a second portion 108a treated by the etching process 112. Herein, the first portion 108b has a diameter D₁ the same as that of the diameter D₁ of the heating electrode 108, and the second portion 108 has a reduced diameter D₂ of about 15-30 nm. The diameter D₂ and the diameter D₁ have a ratio of about 1:4˜1:7. In addition, after the etching process 112, a bottom surface of the second portion 108a will be slightly below a top surface of the dielectric layer 106, and the a depth d2 of about 15-20 nm exists between the second portion 108a and the dielectric layer 106.

Referring to FIG. 5, a metal layer 114 is conformably formed over the dielectric layer 106, thereby covering the heating electrode 108 and filling the recess formed between the second portion 108a of the heating electrode 108 and the dielectric layer 106. The metal layer 114 may comprise noble metal materials such as Co, Ni or refractory metal materials such as Ti, V, Cr, Zr, Mo, Hf, Ta or W.

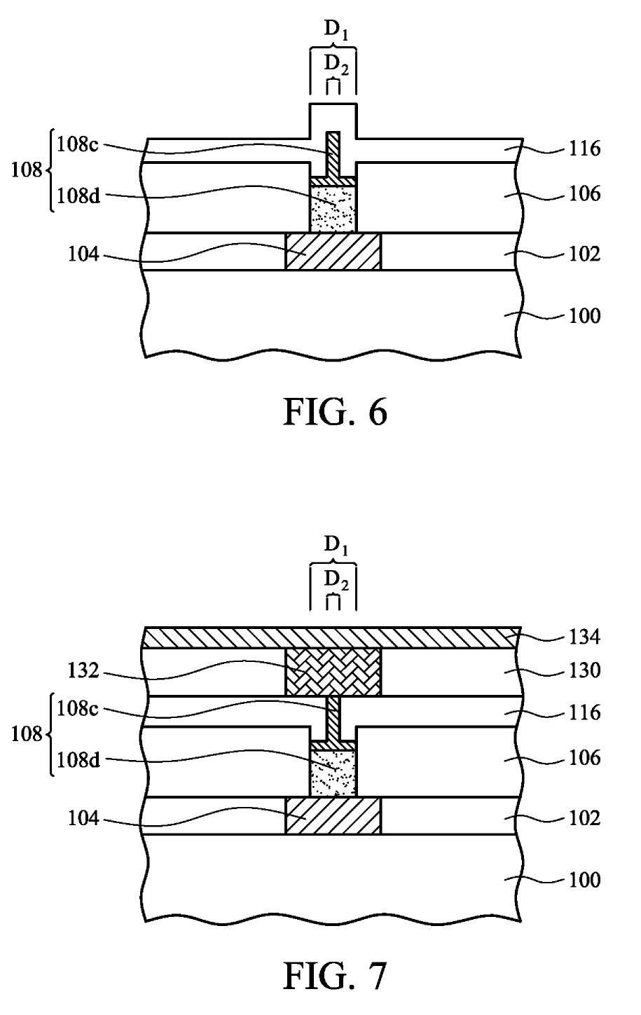

Referring to FIG. 6, an annealing process (not shown) is performed to form metal silicidation between the metal layer 114 and the second portion 108a of the heating electrode 108 and the portions of the first portion 108b (See FIG. 5), thereby conversing the doped polysilicon materials into metal silicides to thereby reduce the contact resistance of the heating electrode 108. As shown in FIG. 6, after the annealing process, the heating electrode 108 comprises a metal silicidation treated third portion 108c and a non-metal silicidation treated fourth portion 108d, wherein the third portion 108c is formed with a reversed T-shaped cross section and the fourth portion 108d is formed with a substantially rectangular cross section. The temperature of the above annealing process can be determined according to the metal material used in the metal layer 114. An etching process (not shown) is then performed to remove the unreacted portion of the metal layer 114. Herein, after removal of the unreacted portion of the metal layer 114, an optional annealing process (not shown) can be further performed to reduce the resistance of the obtained metal silicide.

In one embodiment, an annealing process is first performed to the metal layer 114 comprising Co under a temperature of about 450˜500° C. to react the metal layer 114 with the polysilicon in the heating electrode 108, thereby forming a CoSi metal silicide. Another annealing process is then performed to the metal layer 114 under a temperature of about 750˜800° C. after removing the unreacted portions of the metal layer 114 to convert the CoSi metal silicide of the heating electrode into the CoSi₂ metal silicide.

As shown in FIG. 6, after the annealing process and removal of the unreacted metal layer 108, the heating electrode 108 comprises the third portion 108c of the metal silicide and the fourth portion 108d of the doped polysilicon. Herein, the third portion 108c is formed with a reversed T shaped cross section and still has a diameter D₂, and a bottom surface of the third portion 108c of the heating electrode 108 and the fourth portion 108d of the heating electrode 108 have the original diameter D₁.

Next, a dielectric layer 116 is conformably formed over the dielectric layer 106 and covers the third portion 108c of the heating electrode 108 and fills the recess formed between the third portion 108c of the heating electrode 108 and the dielectric layer 106. Herein, the dielectric layer 116 may comprise silicon oxide formed by, for example, chemical vapor deposition.

Referring to FIG. 7, a planarization process (not shown) such as a chemical mechanical polishing process is performed to remove the dielectric layer 116 formed over the third portion 108c of the heating electrode 108 and portions of the third portion 108c of the heating electrode 108, thereby leaving a substantially planar top surface. A layer of phase change material with thickness of about 50-200 nm is then formed over the dielectric layer 116 to cover the dielectric layer 116 and the third portion 108c of the heating electrode 108. Herein, the phase change materials can be, for example, chalcogenide materials such as Ge—Sb—Te trinary chalcogenide compound or doped chalcogenide compound, and can be formed by, for example, physical or chemical deposition methods. Next, a photolithography and etching process (not shown) are performed to pattern the layer of phase change material, thereby forming a patterned phase change material layer 132 over the third portion 108c of the heating electrode 108 and portions of the dielectric layer 116 adjacent thereto. Herein, the phase change material 132 covers a top surface of third portion 108c of the heating electrode 108.

Next, a layer of dielectric layer is blanketly formed over the substrate 100 to cover the phase change material layer 132 and the dielectric layer 116. A planarization process (not shown) is then performed to remove the dielectric material over the phase change material layer 132, thereby forming a dielectric layer 130 over the dielectric layer 116 and surrounding the phase change material layer 132. Herein, the dielectric material layer 130 may comprise silicon oxide and can be formed by, for example, chemical vapor deposition.

Next, a layer of conductive material (not shown), such as Ti, TiN, TiW, W, Al, or AlN, is then deposited over the dielectric layer 130 by methods such as chemical vapor deposition or sputtering. A photolithography and etching process (not shown) are then performed to pattern and remove portions of the layer of the conductive material, thereby forming an electrode 134. As shown in FIG. 7, the electrode 134 extends along a direction in parallel with the surface of FIG. 7 and is disposed on portions of the dielectric layer 130 to contact with the phase change material layer 132.

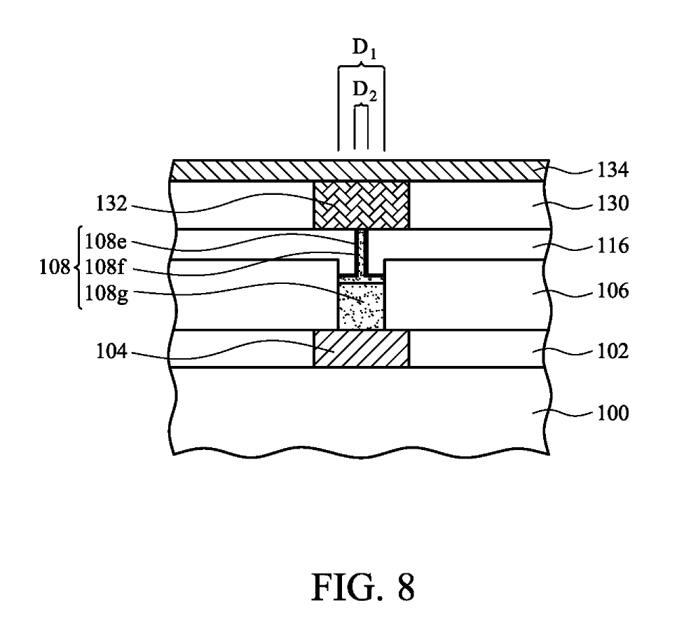

Referring to FIG. 8, a phase change memory device according to another embodiment is illustrated. The phase change memory device illustrated in FIG. 8 is similar with that illustrated in FIG. 7 and a difference therebetween is that the obtained heating electrode 108 in FIG. 8 is formed of three portions, illustrated as a fifth portion 108e, a sixth portion 108f, and the seventh portion 108g. The seventh portion 108g corresponds to the fourth portion 108d in FIG. 7, the fifth portion 108e and the sixth portion 108f correspond to the third portion 108c in FIG. 7. In this embodiment, the fifth portion 108e of the heating electrode 108 is treated by a metal silicidation and is formed as a metal silicide sub-layer and the sixth portion 108f of the heating electrode 108 is not treated by metal silicidation and a doped polysilicon sub-layer. Herein, the heating electrode 108 in FIG. 8 can be fabricated according to the processes illustrated in FIGS. 2-6 and the heating electrode 108 is not fully silicided. This can be achieved by controlling times in the first annealing process or a thickness of the metal layer 114.

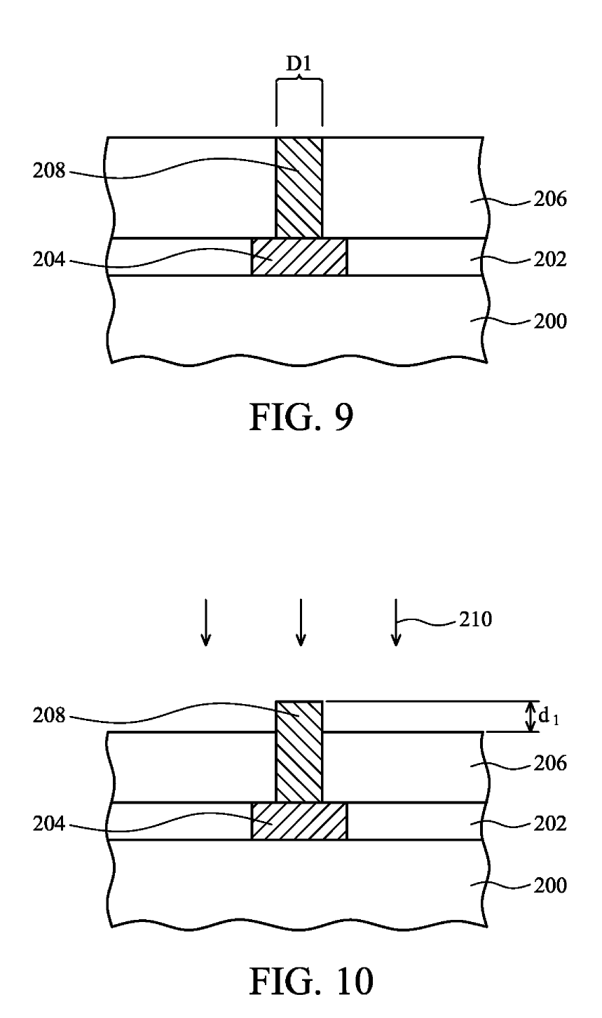

FIGS. 9-14 are schematic diagrams showing fabrication steps of a method for fabricating a phase change memory device according to another exemplary embodiment. In this embodiment, only fabricating of a phase change memory cell in a phase change memory device is illustrated. Note that the phase change memory device in this embodiment can be further formed with a plurality of phase change memory cells and is not limited to the illustrations in FIGS. 9-14.

Referring to FIG. 9, a semiconductor structure such as a silicon substrate is first provided, having semiconductor devices and/or other conductive interconnecting structures covered by a dielectric layer formed thereon. The semiconductor devices (not shown) can be, for example, transistors or diodes. To those skilled in the art, the above active device can be electrically connected with the phase change memory cell by conductive interconnecting structures formed at suitable locations, thereby controlling memory status of the memory cell. The active devices and conductive components, however, are not shown in FIG. 9 for simplicity and only a planar substrate 200 is illustrated in FIG. 9.

Next, an electrode 204 is formed over the substrate 200. As shown in FIG. 9, the electrode 204 can be, for example, a metal line extending along a direction perpendicular to the surface of FIG. 9 or a metal plug. The electrode 204 is disposed over a portion of the substrate 200. Herein, as an example of the metal line process, a layer of conductive material such as Ti, TiN, TiW, W, WN, WSi, TaN, or doped polysilicon, is first blanketly formed over the substrate 100 by methods such as chemical vapor deposition or sputtering. A photolithography process (not shown) is then performed to remove portions of the layer of conductive material to form the electrode 204.

Next, a layer of dielectric material is blanketly formed over the substrate 200 to cover the electrode 204. Herein, the dielectric material can be, for example, borophosphosilicate glass (BPSG), silicon oxide or silicon nitride. A planarization process (not shown) is then performed to remove the portion of the dielectric material over the electrode 204, thus leaving a dielectric layer 202 over the substrate 200 to surround the electrode 204.

Next, a layer of conductive material is blanketly deposited over the dielectric layer 202. A photolithography and etching process (not shown) are then performed to define the conductive layer, thereby forming a conductive rod as heating electrode 208. As shown in FIG. 9, the heating electrode 208 penetrates the dielectric layer 206 and contacts the electrode 204. The heating electrode 208 has a diameter D₁ of about 90-110 nm.

Next, a dielectric layer 206 is deposited over the dielectric layer 202 and covers the heating electrode 208. The thickness of dielectric layer 206 is higher than the height of heating electrode 208. The dielectric layer may comprise silicon dioxide formed by high density plasma chemical vapor deposition. A planarization process (not shown) is then performed to remove the dielectric material over the heating electrode 208 and expose the top surface of heating electrode 208. In this embodiment, the heating electrode 208 may comprise noble metal materials such as Co, Ni or refractory metal materials such as Ti, V, Cr, Zr, Mo, Hf, Ta or W.

Referring to FIG. 10, an etching process 210 is performed to selectively remove portions of the dielectric layer 206 and expose portions of the heating electrode 208. Herein the etching process 210 preferably is a wet etching process and a thickness d1 of about 130-150 nm of the dielectric layer 206 is removed after the etching process 210, thereby partially exposing portions of the heating electrode 208.

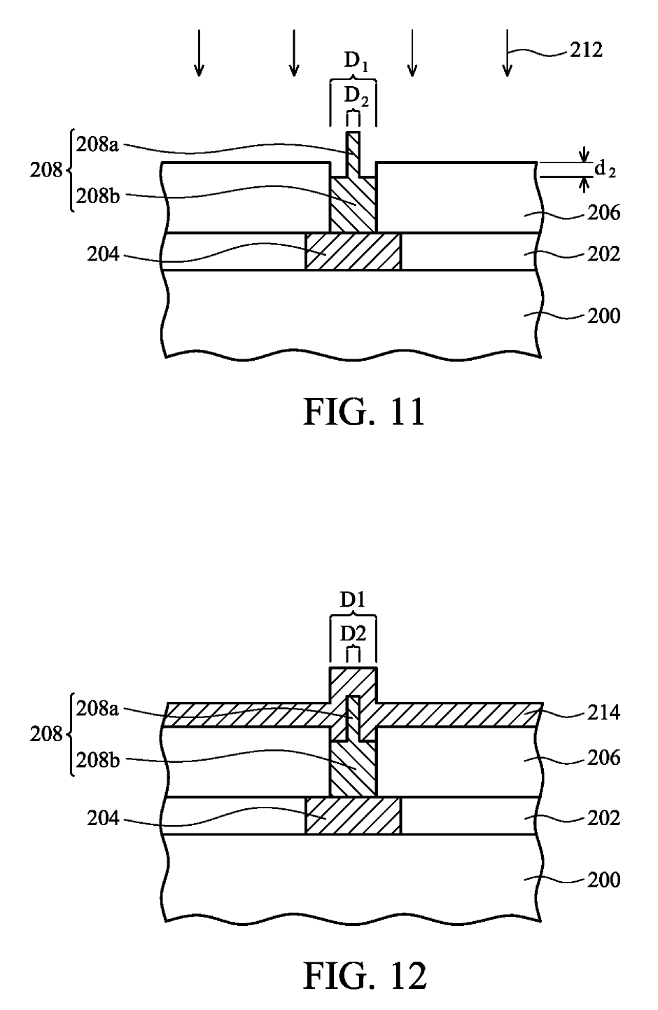

Referring to FIG. 11, an etching process 212 is then performed to selectively remove the portion of the heating electrode 208 exposed by the dielectric layer 206. Herein, the etching process preferably is a wet etching process. Thus, after the etching process 212, the portion of the heating electrode 208 exposed by the dielectric layer is formed with a reversed T shaped cross section.

As shown in FIG. 11, after the etching process 212, the heating electrode 208 is substantially divided into two portions, one is a first portion 208b not treated by the etching process 212 and the other is a second portion 208a treated by the etching process 212. Herein, the first portion 208b has a diameter D₁ the same as that of the diameter D₁ of the heating electrode 208, and the second portion 208a has a reduced diameter D₂ of about 15-30 nm. The diameter D₂ and the diameter D₁ has a ratio of about 1:4˜1:7. In addition, after the etching process 212, a bottom surface of the second portion 208a is slightly below a top surface of the dielectric layer 206, and a depth d2 of about 15-20 nm exists between the second portion 208a and the dielectric layer 206.

Referring to FIG. 12, a semiconductive layer 214 is conformably formed over the dielectric layer 206, thereby covering the heating electrode 208 and filling the recess formed between the second portion 208a of the heating electrode 208 and the dielectric layer 206. The semiconductor layer 214 may comprise undoped polysilicon or amorphous silicon, having a thickness of about 5-30 nm and a resistance of about 1e5Ω-cm.

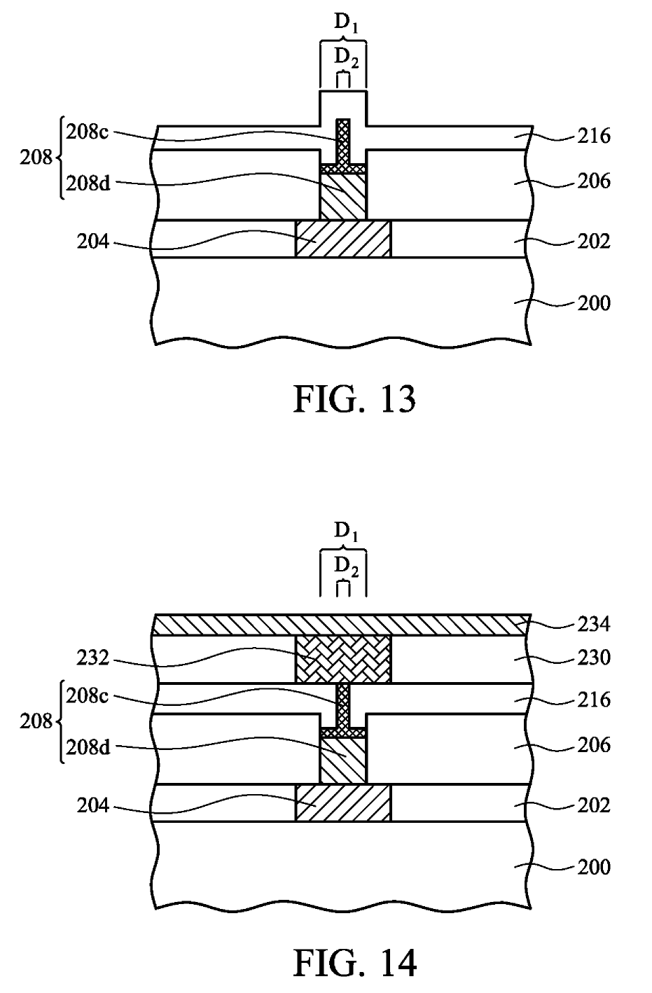

Referring to FIG. 13, an annealing process (not shown) is performed to form metal silicidation between the semiconductor layer 214 and the second portion 208a of the heating electrode 208 and the portions of the first portion 208b (See FIG. 11), thereby conversing the metal materials into metal silicides to thereby reduce the contact resistance of the heating electrode 208. As shown in FIG. 13, after the annealing process, the heating electrode 208 comprises a metal silicidation treated third portion 208c and a non-metal silicidation treated fourth portion 208d, wherein the third portion 208c is formed with a reversed T-shaped cross section and the fourth portion 208d is formed with a substantially rectangular cross section. The temperature of the above annealing process can be determined according to the metal material used in the heating electrode 208.

An etching process (not shown) is then performed to remove the unreacted portion of the semiconductor layer 214. Herein, after removal of the unreacted portion of the semiconductor layer 214, an optional annealing process (not shown) can be further performed to improve the resistance of the obtained metal silicide. In another embodiment, the semiconductor layer 214 has a thickness of about 5-30 nm and the semiconductor layer 214 may be mixed with the dielectric layer 206 after the first annealing process, such that the removal of the unreacted portion of the semiconductor layer 214 can be omitted.

In one embodiment, an annealing process is first performed to the heating electrode 208 comprising Co under a temperature of about 450˜500° C. to react the heating electrode 208 with the semiconductor layer 214, thereby forming a CoSi metal silicide. Another annealing process is then performed under a temperature of about 750˜800° C. after removing the unreacted portions of the semiconductor layer 214 to convert the CoSi metal silicide of the heating electrode into CoSi₂ metal silicide.

As shown in FIG. 13, after the annealing process and removal of the unreacted semiconductor layer 214, the heating electrode 208 comprises the third portion 208c of the metal silicide and the fourth portion 208d of noble metal materials or refractory metal materials. Herein, the third portion 208c is formed with a reversed T shaped cross section and still has a diameter D₂, and a bottom surface of the third portion 208c of the heating electrode 208 and the fourth portion 208d of the heating electrode 208 have the original diameter D₁.

Next, a dielectric layer 216 is conformably formed over the dielectric layer 206 and covers the third portion 208c of the heating electrode 208 and fills the recess formed between the third portion 208c of the heating electrode 208 and the dielectric layer 206. Herein, the dielectric layer 216 may comprise silicon oxide formed by, for example, chemical vapor deposition.

Referring to FIG. 14, a planarization process (not shown) such as a chemical mechanical polishing process is performed to remove the dielectric layer 216 formed over the third portion 208c of the heating electrode 208 and portions of the third portion 208c of the heating electrode 208, thereby leaving a substantially planar top surface. A layer of phase change material with thickness of about 50-200 nm is then formed over the dielectric layer 216 to cover the dielectric layer 216 and the third portion 208c of the heating electrode 208. Herein, the phase change materials can be, for example, chalcogenide materials such as Ge—Sb—Te trinary chalcogenide compound or doped chalcogenide compound, and can be formed by, for example, physical or chemical deposition methods. Next, a photolithography and etching process (not shown) are performed to pattern the layer of phase change material, thereby forming a patterned phase change material layer 232 over the third portion 208c of the heating electrode 208 and portions of the dielectric layer 216 adjacent thereto. Herein, the phase change material 232 covers a top surface of third portion 208c of the heating electrode 208.

Next, a layer of dielectric layer is blanketly formed over the substrate 200 to cover the phase change material layer 232 and the dielectric layer 216. A planarization process (not shown) is then performed to remove the dielectric material over the phase change material layer 232, thereby forming a dielectric layer 230 over the dielectric layer 216 and surrounding the phase change material layer 232. Herein, the dielectric material layer 230 may comprise silicon oxide and can be formed by, for example, chemical vapor deposition.

Next, a layer of conductive material (not shown), such as Ti, TiN, TiW, W, Al, or AlN, is then deposited over the dielectric layer 230 by methods such as chemical vapor deposition or sputtering. A photolithography and etching process (not shown) are then performed to pattern and remove portions of the layer of the conductive material, thereby forming an electrode 234. As shown in FIG. 14, the electrode 234 extends along a direction in parallel with the surface of FIG. 14 and is disposed on portions of the dielectric layer 230 to contact with the phase change material layer 232.

As the above describes, a phase change memory device (e.g. the phase change memory device illustrated in FIGS. 7, 8 and 14) is provided, comprising a substrate (e.g. the substrate 100/200), a first dielectric layer (e.g. the dielectric layer 102/202) disposed over the substrate, a first electrode (e.g. the electrode 104/204) disposed in the first dielectric layer, a second dielectric layer (e.g. the dielectric layers including 106 and 116 or 206 and 216) formed over the first dielectric layer, covering the first electrode, a heating electrode (e.g. the heating electrode 108/208) disposed in the second dielectric layer, contacting the first electrode, a phase change material layer (e.g. the phase change material layer 132/232) disposed over the second dielectric layer, contacting the heating electrode, and a second electrode (the electrode 134/234) disposed over the phase change material layer, wherein the heating electrode comprises a first portion (e.g. 108d/108g/208d) contacting the first electrode and a second portion contacting the phase change material layer, and the second portion (108c/combinations of 108e and 108f/208c) of the heating electrode comprises metal silicides and the first portion of the heating electrode comprises no metal silicides.

In the above embodiments, the second portion of the heating electrode is formed with a reversed T-shaped cross section. Compared with the diameter of the heating electrode obtained by the conventional photolithography and etching processes, the phase change memory device of the invention can have an interface of a reduced diameter of about 15-30 nm between the second portion of the heating electrode and the phase change memory layer, thereby overcoming diameter limitations of the heating electrode due to photolithography processes and thus reducing reset currents of the phase change memory device.

Moreover, in one embodiment, a second portion of the heating electrode in the phase change memory device contacting the phase change material layer comprises metal silicide and a first portion of the heating electrode comprises no metal silicides. Because the first portion of the heating electrode comprises doped polysilicon and the second portion of the heating electrode comprises metal silicides, a contact resistance between the heating electrode and the phase change material layer is reduced by a partial or full silicided second portion of the heating electrode, thus improving heating efficiency of phase change materials and further reducing reset currents of the phase change memory device.

Moreover, in another embodiment, a second portion of the heating electrode in the phase change memory device contacting the phase change material layer comprises metal silicide and a first portion of the heating electrode comprises no metal silicides. Because the first portion of the heating electrode comprises noble metal materials or refractory metal materials and the second portion of the heating electrode comprises metal silicides, resistance of the heating electrode is reduced by using the metal materials in the first portion of the heating electrode and chemical stability can be improved by using the metal silicide as the second portion of the heating electrode, thereby preventing undesired chemical reactions to occur between the metal materials in the first portion of the heating electrode and the phase change material layer and improving reliability of the phase change memory device.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

1-8. (canceled)

9. A method for fabricating phase change memory device, comprising:
providing a substrate with a first electrode formed thereover;
forming a first dielectric layer over the substrate, wherein the first dielectric layer surrounds the first electrode and exposes a top surface of the first electrode;
forming a second dielectric layer over the first dielectric layer, covering the first electrode and the first dielectric layer;
forming a heating electrode in the second dielectric layer;
forming a phase change material layer over the second dielectric layer;
and forming a second electrode over the phase change material layer to contact thereof, wherein the heating electrode comprises a first portion contacting the first electrode and a second portion contacting the phase change material layer, and the second portion of the heating electrode comprises metal silicides and the first portion of the heating electrode comprises doped polysilicon, noble metal materials or refractory metal materials.

10. The method as claimed in claim 9, wherein the first portion of the heating electrode comprises doped polysilicon and forming the heating electrode in the second dielectric layer comprises:
performing a first etching process to remove portions of the second dielectric layer and exposing portions of the heating electrode;
performing a second etching process, partially removing the portions of the heating electrode exposed from the second dielectric layer such that the portions of the heating electrode have a reduced diameter;
conformably forming a layer of refractory metal material or noble metal material over the second dielectric layer, covering the portions of the heating electrode;
performing a first annealing process to generate metal silicidation between the portions of the heating electrode and the layer of refractory metal material or noble metal material contacting therewith and not generate metal silicidation between the second dielectric layer and the layer of refractory metal material or noble metal material contacting therewith;
and removing the portion of the layer of refractory metal material or noble metal material not reacting with the portions of the heating electrode to from the first and second portions of the heating electrode.

11. The method as claimed in claim 10, further comprising performing a second annealing process after removing the portion of the layer of refractory metal material or noble metal material not reacting with the portions of the heating electrode.

12. The method as claimed in claim 9, wherein the first portion of the heating electrode comprises refractory metal material or noble metal material and forming the heating electrode in the second dielectric layer comprises:
performing a first etching process, removing portions of the second dielectric layer and exposing portions of the heating electrode;
performing a second etching process, partially removing the portions of the heating electrode exposed from the second dielectric layer, such that the portions of the heating electrode have a reduced diameter; conformably forming a layer of polysilicon or amorphous silicon over the second dielectric layer, covering the portions of the heating electrode;
performing a first annealing process to cause metal silicidation between the portion of the heating electrode and the layer of polysilicon or amorphous silicon contacting therewith, thereby forming the first and second portions of the heating electrode in the second dielectric layer.

13. The method as claimed in claim 12, further comprising removing the portion of the layer of polysilicon or amorphous silicon not reacting with the portions of the heating electrode.

14. The method as claimed in claim 13, further comprising performing a second annealing process after removing the portion of the layer of polysilicon or amorphous silicon not reacting with the portions of the heating electrode.

15. The method as claimed in claim 9, wherein the second portion of the heating electrode comprises a reversed T-shaped cross section.

16. The method as claimed in claim 9, wherein an interface between the second portion of the heating electrode and the phase change material layer has a diameter of not more than 30 nm.

17. The method as claimed in claim 9, wherein the phase change material comprises chalcogenide materials.

18. The method as claimed in claim 9, wherein second portion of the heating electrode consists essentially of the metal silicide.
